(19) United States
(12) Patent Application Publication
(10) Pub. No.: US 2011/0076789 A1
(43) Pub. Date: Mar. 31, 2011

(54) MANUFACTURING METHOD OF SEMICONDUCTOR DEVICE AND SUBSTRATE PROCESSING APPARATUS

(75) Inventor: Jun KURODA, Toyama-shi (JP)

(73) Assignee: HITACHI KOKUSAI ELECTRIC INC., TOKYO (JP)

(21) Appl. No.: 12/890,954

(22) Filed: Sep. 27, 2010

(30) Foreign Application Priority Data
Sep. 28, 2009 (JP) 2009-222922
Jul. 14, 2010 (JP) 2010-160137

(51) Int. Cl. H01L 21/66; G06F 19/00

(52) U.S. Cl. 438/14; 700/121; 257/E21.529

(57) ABSTRACT

To reduce the number of photomasks for forming an ion injection mask, then reduce a manufacturing cost of a semiconductor device, accurately control a shape and a position of an ion implantation region into a substrate, and improve a manufacturing yield of the semiconductor device. A manufacturing method of a semiconductor device comprises the steps of: forming an alignment mark on a substrate; forming a second resist pattern on the substrate on which the alignment mark is formed; forming a first ion implantation region by injecting a first ion into an exposure surface of the substrate; forming a thin film on the second resist pattern and on the first ion implantation region; forming a thin film pattern that covers an outer edge of the first ion implantation region by reducing a prescribed portion of the thin film; forming a second ion implantation region by injecting a second ion into the exposure surface of the first ion implantation region; and removing the thin film pattern and the second resist pattern.

### CROSS-REFERENCE TO RELATED APPLICATION

This U.S. non-provisional patent application claims priority under 35 U.S.C. §119 of Japanese Patent Application No. JP2009-222922 filed on Sep. 28, 2009, and Japanese Patent Application No. JP2010-160137 filed on Jul. 14, 2010, the contents of which are hereby incorporated by reference into this application.

### BACKGROUND

1. Technical Field

The present invention relates to a manufacturing method of a semiconductor device having a photolithography step, and a substrate processing apparatus for executing this method.

2. Description of Related Art

As a step of the manufacturing steps of a semiconductor device such as a memory device, for example, a photolithography step is executed, comprising the steps of forming a resist film on a substrate such as a silicon wafer; then irradiating (exposing) the resist film with (to) lights through a photomask and developing the resist film after exposure; and forming a resist pattern on the substrate. The formed resist pattern is used as a mask (called an ion injection mask hereafter), etc, for injecting ions into a surface of the substrate, being a base.

In recent years, as higher integration of the semiconductor device is progressed, it is necessary to have a technique wherein the step of forming a first resist pattern on the substrate, and the step of forming a second resist pattern on the substrate, are sequentially executed, to thereby synthesize the first resist pattern and the second resist pattern so as to be accurately superposed on each other.

According to a conventional art, in order to accurately form the ion injection mask, a relative position of the first resist pattern and the second resist pattern needs to be controlled to fall within an allowable range. As a method of controlling the relative position, for example, a method of previously forming an alignment mark on a substrate, and thereafter forming the first resist pattern on the substrate with the alignment mark as a reference position, and thereafter forming the second resist pattern on the substrate with the alignment mark as a reference position, can be considered.

However, the above-described method requires three photomasks in total, such as a photomask for forming the alignment mark, a photomask for forming the first resist pattern, and a photomask for forming the second resist pattern, thus increasing a manufacturing cost of the semiconductor device in some cases. Further, in order to control the relative position within an allowable range, extensive stepper equipment is required, thus involving a problem that a cost is increased. Moreover, in the above-described method, when the second resist pattern is formed, the first resist pattern formed prior to the second resist pattern, suffers damage due to heat and solvent, thereby deteriorating a quality of the ion injection mask, and the ion injection mask with a desired shape can not be obtained in some cases. Further, for example, when a misalignment is generated in a forming position of the first resist pattern, the relative position of the first resist pattern and the second resist pattern does not fall within an allowable range even if the forming position of the second resist pattern is accurately decided, and a desired shape of the ion injection mask can not be obtained in some cases. As a result, irregular shape and position of an ion implantation region on the substrate are formed, to thereby deteriorate a production yield of the semiconductor device in some cases.

### SUMMARY OF THE INVENTION

Therefore, an object of the present invention is to provide a manufacturing method of a semiconductor device and a substrate processing apparatus capable of cutting down the number of photomasks for forming the ion injection mask and reducing the manufacturing cost of the semiconductor device, and improving a manufacturing yield of the semiconductor device by accurately controlling the shape and position of an ion implantation region into a substrate.

According to an aspect of the present invention, a manufacturing method of a semiconductor device is provided, comprising the steps of:

forming a first resist film on a substrate;

forming a first resist pattern on the substrate by drawing a pattern on the first resist film;

forming an alignment mark on the substrate by etching an exposure surface of the substrate, with the first resist pattern as a mask;

removing the first resist pattern;

forming a second resist film on the substrate on which the alignment mark is formed;

forming a second resist pattern on the substrate by drawing and developing a pattern on the second resist film, with the alignment mark as a reference position;

forming a first ion implantation region on the substrate by injecting a first ion into the exposure surface of the substrate, with the second resist pattern as a mask;

forming a thin film on the second resist pattern and on the first ion implantation region;

forming a thin film pattern that covers an outer edge of the first ion implantation region by exposing a part of the first ion implantation region by reducing the thin film by a specified thickness while leaving the thin film on a side wall of the first resist pattern;

forming a second ion implantation region in the first ion implantation region by injecting a second ion into the exposure surface of the first ion implantation region, with the thin film pattern as a mask; and

removing the thin film pattern and the second resist pattern.

According to other aspect of the present invention, a substrate processing apparatus is provided, comprising:

a processing chamber that processes substrates;

a first source gas supply system that supplies Si contained source into the processing chamber;

a second source gas supply system that supplies an oxide source into the processing chamber;

a catalyst supply system that supplies catalyst into the processing chamber;

a heating unit that heats the substrate; and

a controller that controls at least the first source gas supply system, the second source gas supply system, the catalyst supply system, and the heating unit, so as to repeat a cycle of a Si contained source supplying step for supplying the Si contained source and the catalyst into the processing chamber, and an oxide source supplying step for supplying the oxide source and the catalyst into the processing chamber, with this cycle set as one cycle.

According to the manufacturing method of the semiconductor device and the substrate processing apparatus of the present invention, the number of photomasks for forming the ion injection mask can be cut down, and the manufacturing cost of the semiconductor device can be reduced, and the manufacturing yield of the semiconductor device can be improved by accurately controlling the shape and position of the ion implantation region into the substrate.

### BRIEF DESCRIPTION OF THE DRAWINGS

FIG. 1 is a perspective view of a substrate processing apparatus according to an embodiment of the present invention.

FIG. 2 is a vertical cross sectional view of a processing furnace of the substrate processing apparatus according to an embodiment of the present invention.

FIG. 3 is a cross sectional view cut along the line A-A of FIG. 2.

FIG. 4 is a schematic view explaining a first half part of the substrate processing step according to an embodiment of the present invention, showing a state that a second resist pattern is formed after an alignment mark is formed on a wafer.

FIG. 5 is a schematic view explaining a second half part of the substrate processing step according to an embodiment of the present invention, showing a state that a first ion implantation region is formed, with the second resist pattern as an ion injection mask and thereafter a thin film pattern covering an outer edge of the first ion implantation region is formed, and a second ion implantation region is formed, with the thin film pattern as the ion injection mask.

FIG. 6 is a view exemplifying a schematic gas supply sequence when a thin film is formed by an ALD method, in the substrate processing step according to an embodiment of the present invention.

FIG. 7 is a schematic view showing a step of a conventional substrate processing steps.

FIG. 8 is a schematic view showing a step of the conventional substrate processing steps.

FIG. 9 is a schematic view showing a step of the conventional substrate processing steps.

FIG. 10 is a schematic view showing a step of the conventional substrate processing steps.

### DESCRIPTION OF PREFERRED EMBODIMENTS OF THE INVENTION

### An Embodiment of the Present Invention

An embodiment of the present invention will be described hereafter, with reference to the drawings.

A substrate processing apparatus according to this embodiment is constituted as an example of a semiconductor manufacturing device used in manufacture of a memory device such as flush memory, DRAM (Dynamic Random Access Memory), SRAM (Static Random Access Memory) and a semiconductor device such as a logic device. In the explanation given hereafter, as an example of the substrate processing apparatus, a vertical apparatus for applying film formation processing to substrates will be described. However, the present invention is not limited to application to the vertical apparatus, and can be applied to, for example, a single wafer processor. Further, the present invention is not limited to a film formation processing of a SiO₂ film (silicon oxide film) shown below, in which the Si contained source, oxide source, and catalyst are combined, and can be applied to other film formation processing capable of forming a film at a low temperature, such as a film formation processing using for example an optical energy.

### (1) Structure of the Substrate Processing Apparatus

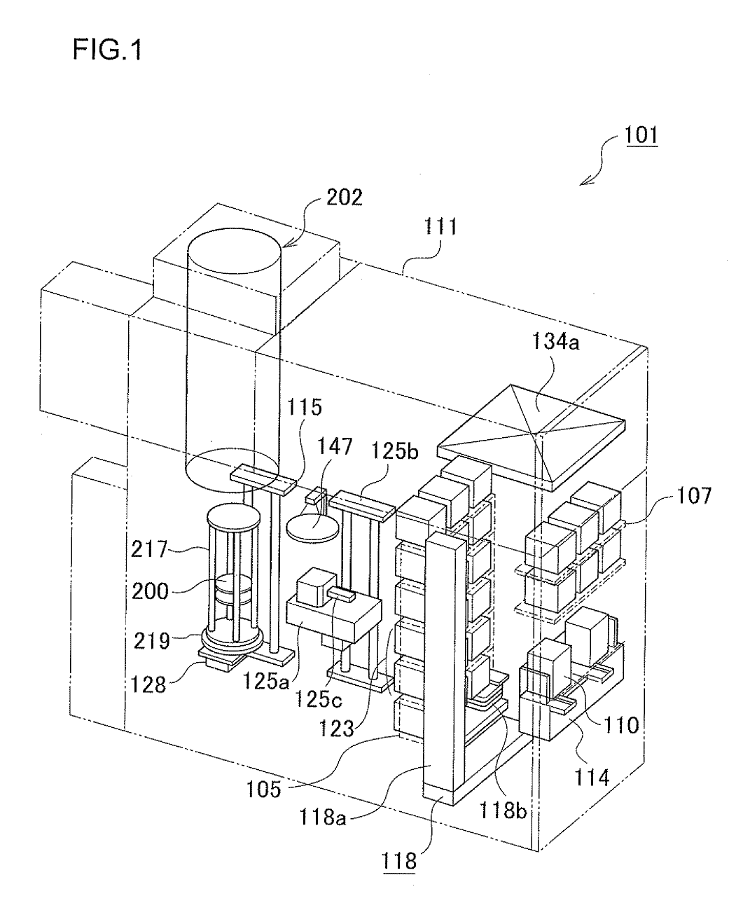

First, a structural example of a substrate processing apparatus 101 according to this embodiment will be described, with reference to FIG. 1.

As shown in FIG. 1, the substrate processing apparatus 101 of this example has a casing 111. A front maintenance port, being an opening part provided to enable maintenance to be carried out in the casing 111, is formed in a lower part of a front wall 1 (right side in the figure) of the casing 111. A front maintenance door for opening and closing the front maintenance port is provided to the front maintenance port. A cassette 110, being a wafer carrier (substrate container) for storing a plurality of wafers 200 is used for carrying a wafer (substrate) 200 made of silicon to/outside the casing 111. A cassette loading/unloading port (substrate container loading/unloading port), being an opening for carrying the cassette 110 to/outside the casing 111, is formed on a front maintenance door 104. The cassette loading/unloading port is opened and closed by a front shutter (substrate container loading/unloading port open/close mechanism). A cassette stage (substrate container transfer table) 114 is provided to inside of the casing 111 of the cassette loading/unloading port. The cassette 110 is placed on the cassette stage 114 by an in-step carrier not shown, and is unloaded to the outside of the casing 111 from the cassette stage 114.

The cassette 110 is placed on the cassette stage 114 by the in-step carrier, so that the wafer 200 in the cassette 110 is set in a vertical posture and a wafer charging and discharging port of the cassette 110 faces upward. The cassette stage 114 is formed, so that the cassette 110 can be rotated vertically by 90° facing rearward of the casing 111, with the wafer 200 in the cassette 110 set in a horizontal posture, and the wafer charging and discharging port of the cassette 110 can face rearward of the casing 111.

A cassette shelf (substrate container placement shelf) 105 is installed in approximately a longitudinally central part of the casing 111. The cassette shelf 105 is formed so as to store a plurality of cassettes 110 in multiple stages and multiple rows. A transfer shelf 123 is provided to the cassette shelf 105, for storing the cassette 110, being a carrying object of a wafer transfer mechanism as will be described later. Further, a preliminary cassette shelf 107 is provided in an upper part of the cassette stage 114, so that the cassette 110 is stored preliminarily.

A cassette carrier (substrate container carrier) 118 is provided between the cassette stage 114 and the cassette shelf 105. The cassette carrier 118 includes a cassette elevator (substrate container elevating mechanism) 118a that can be elevated while holding the cassette 110, and a cassette transfer mechanism (substrate container transfer mechanism), being horizontally movable transfer mechanism while holding the cassette 110. By continuous operation of the cassette elevator 118a and the cassette transfer mechanism 118b, the cassette 110 is carried among the cassette stage 114, the cassette shelf 105, the preliminary cassette shelf 107, and the transfer shelf 123.

The wafer transfer mechanism (substrate transfer mechanism) is provided in the rearward of the cassette shelf 105. The wafer transfer mechanism includes a wafer transfer device (substrate transfer device) 125a capable of horizontally rotating or straightly moving the wafer 200, and a wafer transfer device elevator (substrate transfer device elevating mechanism) 125b for elevating the wafer transfer device 125a. Note that the wafer transfer device 125a includes a tweezer (substrate holding body) for holding the wafer 200 in a horizontal posture. By continuous operation of the wafer transfer device 125a and the wafer transfer device elevator 125b, the wafer 200 is picked up from the cassette 110 on the transfer shelf 123 and is charged into a boat (substrate holding tool) 217 as will be described later and is discharged from the boat 217, to be stored in the cassette 110 on the transfer shelf 123.

A processing furnace 202 is provided to a rear upper part of the casing 111. An opening is provided to a lower end portion of the processing furnace 202, and the opening is opened and closed by a furnace port shutter (furnace port open/close mechanism) 147. The structure of the processing furnace 202 will be described later.

A boat elevator (substrate holding tool elevating mechanism) 115, being an elevating mechanism for loading and unloading the boat 217 to/inside the processing furnace 202, is provided in a lower part of the processing furnace 202. An arm 128, being a connecting tool, is provided to an elevation table of the boat elevator 115. A seal cap 219, being a lid member, is provided on the arm 128 in a horizontal posture, for vertically supporting the boat 217 and air-tightly closing the lower end portion of the processing furnace 202 when the boat 217 is elevated.

The boat 217 has a plurality of holding members, and a plurality of (for example about 50 to 150) wafers 200 in a horizontal posture, so as to be arranged in a vertical direction in such a manner as being held with their centers aligned.

A clean unit 134a including a supply fan and a dust-free filter is provided in an upper part of the cassette shelf 105. The clean unit 134a is formed so that clean air, being cleaned atmosphere, is circulated through the casing 111.

Further, a clean unit (not shown) including the supply fan and the dust-free filter for supplying clean air, is installed on a left side end portion of the casing 111, being an opposite side to the wafer transfer device elevator 125b and the boat elevator 115. The clean air blown out from the clean unit not shown, is circulated through the wafer transfer device 125a and the boat 217, and thereafter is sucked into an exhaust device not shown, and is exhausted to outside of the casing 111.

### (2) Operation of the Substrate Processing Apparatus

Next, an operation of a substrate processing apparatus 101 according to an example of the present invention will be described.

First, a cassette loading/unloading port 112 is opened by a front shutter 113, prior to placement of the cassette 110 on the cassette stage 114. Thereafter, the cassette 110 is loaded from the cassette loading/unloading port 112 by the in-step carrier, and is placed on the cassette stage 114, so that the wafer 200 is set in a vertical posture and the wafer charging and discharging port of the cassette 110 faces upward. Thereafter, the cassette 110 is rotated by 90° vertically facing the rearward of the casing 111. As a result, the wafer 200 in the cassette 110 is set in a horizontal posture, and the wafer charging and discharging port of the cassette 110 faces rearward in the casing 111.

Next, the cassette 110 is automatically transferred to a cassette shelf 105 or a designated shelf position of the preliminary cassette shelf 107 by the cassette carrier 118, and is temporarily stored therein, and thereafter is transferred to the transfer shelf 123 from the cassette shelf 105 or the preliminary cassette shelf 107, or is directly carried to the transfer shelf 123.

When the cassette 110 is transferred to the transfer shelf 123, the wafer 200 is picked up from the cassette 110 through the wafer charging and discharging port, by a tweezer 125c of the wafer transfer device 125a, and is charged into the boat 217 located rearward of the transfer chamber 124 by continuous operation of the wafer transfer device 125a and the wafer transfer device elevator 125b. The wafer transfer mechanism 125 that transfers the wafer 200 to the boat 217, returns to the cassette 110 so that the next wafer 200 is charged into the boat 217.

When the previously designated number of wafers 200 are charged into the boat 217, the lower end portion of the processing furnace 202 closed by the furnace port shutter 147, is opened by the furnace port shutter 147. Subsequently, by elevating the seal cap 219 by the boat elevator 115, the boat 217 holding a group of the wafers 200 is loaded into the processing furnace 202 (loading). After loading, arbitrary processing is applied to the wafer 200 in the processing furnace 202. Such processing will be described later. After processing, the wafer 200 and the cassette 110 are discharged to the outside of the casing 111 in a reversed procedure to the aforementioned procedure.

### (3) Structure of the Processing Furnace

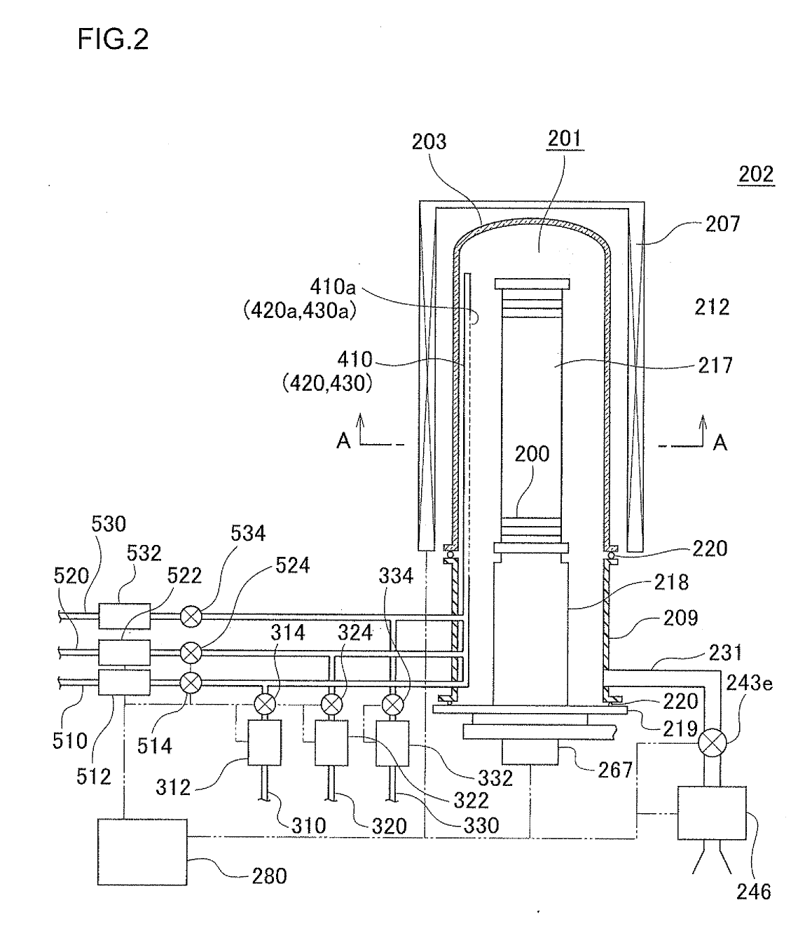

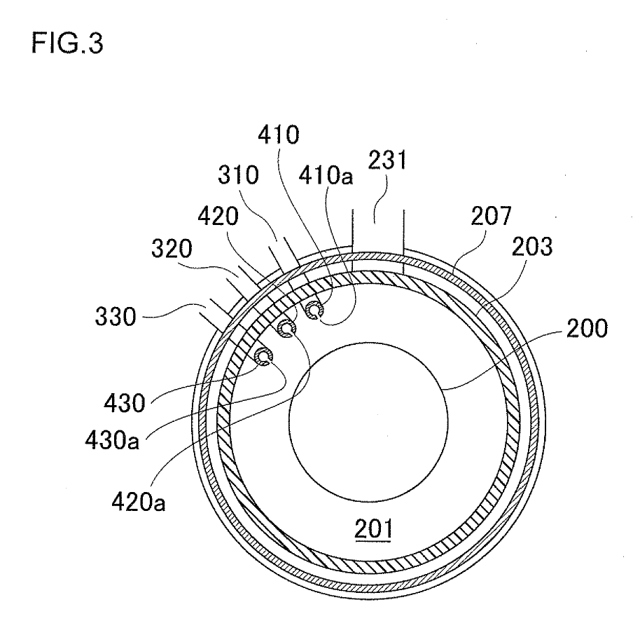

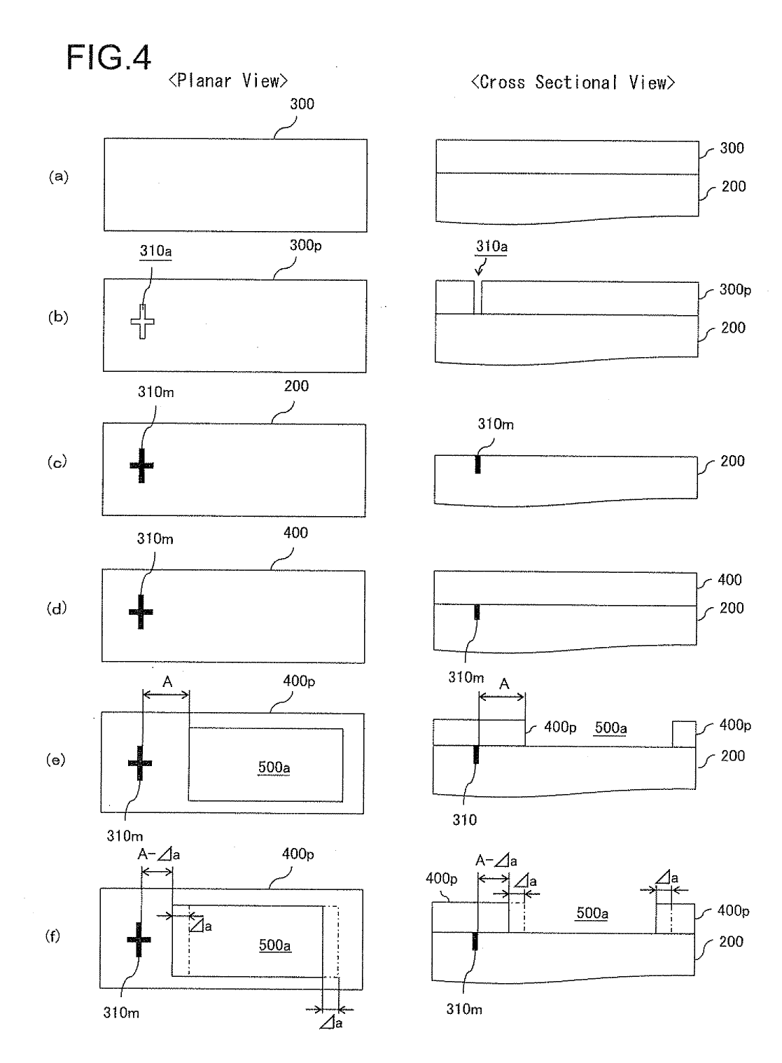

Subsequently, the structure of the processing furnace 202 according to this embodiment will be described, with reference to FIG. 2 and FIG. 3.

### (Processing Furnace)

The processing furnace 202 includes a reaction tube 203 and a manifold 209. The reaction tube 203 is made of a non-metal material having a heat resistant property such as quartz (SiO₂) and silicon carbide (SiC), and has a cylindrical shape with an upper end closed and a lower end opened. The manifold 209 is made of a metal material such as SUS, and has a cylindrical shape with an upper end and a lower end opened. The reaction tube 203 is supported vertically by the manifold 209 from the lower end side. The reaction tube 203 and the manifold 209 are mutually concentrically arranged. The lower end (furnace port) of the manifold 209 is air-tightly sealed by a disc-like seal cap 219, being a lid member, when the aforementioned boat elevator 115 is elevated. An O-ring 220, being a sealing member for air-tightly sealing the inside of the reaction tube 203, is provided between the lower end of the manifold 209 and the seal cap 219.

A processing chamber 201 for processing the wafer 200 is formed by the reaction tube 203, the manifold 209 and the seal cap 219. The boat 217, being a substrate holding tool, is inserted from below into the reaction tube 203 (into the processing chamber 201). Inner diameters of the reaction tube 203 and the manifold 209 are larger than a maximum outer shape of the boat 217 into which the wafer 200 is charged.

A plurality of (for example, 75 to 100) wafers 200 are held in the boat 217 at prescribed intervals (substrate pitch intervals) in multiple stages in a horizontal posture. The boat 217 is mounted on a heat insulating cap 218 for insulating heat conduction from the boat 217. The heat insulating cap 218 is supported from below by a rotation shaft 255. The rotation shaft 255 is provided so as to pass through a central part of the seal cap 219 while holding air-tightness inside of the processing chamber 201. A rotation mechanism 267 for rotating the rotation shaft 255 is provided in a lower part of the seal cap 219. By rotating the rotation shaft 255 by the rotation mechanism 267, the boat 217 on which a plurality of wafers 200 are mounted, can be rotated while air-tightly holding the inside of the processing chamber 201.

A heater 207, being a heating means (heating mechanism) is provided to an outer periphery of the reaction tube 203, concentrically with the reaction tube 203. The heater 207 includes a cylindrical-shaped heat insulating member with an upper side closed, has a plurality of heater strands, and has a unit structure with heater strands provided to the heat insulating member. The heater 207 is vertically installed on a heater base by being supported thereby.

### (Gas Supplying Means)

As shown in FIG. 2 and FIG. 3, a first source gas supply tube 310, a second source gas supply tube 320 for supplying source gas, and a catalyst supplying tube 330 for supplying catalyst, are connected to the processing chamber 201.

A first source gas supply source not shown, a mass flow controller 312 and a valve 314 are provided to the first source gas supply tube 310 sequentially from an upstream side. A nozzle 410 is connected to a tip end portion of the first source gas supply tube 310. The nozzle 410 is extended in an upper and lower direction along an inner wall of the reaction tube 203 in an arc-shaped space between the inner wall of the reaction tube 203 and the wafer 200 constituting the processing chamber 201. A plurality of gas supply holes 410a are formed on the side face of the nozzle 410 for supplying the source gas. The gas supply holes 410a have opening areas which are the same from a lower part to an upper part or sloped in sizes toward the upper part, and further they are provided at the same opening pitches.

Further, a carrier gas supply tube 510 for supplying carrier gas, is connected to the first source gas supply tube 310. A first carrier gas supply source not shown, a mass flow controller 512, and a valve 514 are provided to the carrier gas supply tube 510 sequentially from the upstream side.

A second source gas supply source not shown, a mass flow controller 322, and a valve 324 are provided to the second source gas supply tube 320 sequentially from the upstream side. A nozzle 420 is connected to the tip end portion of the second source gas supply tube 320. The nozzle 420 is also extended in the upper and lower direction along the inner wall of the reaction tube 203 in the arc-shaped space between the inner wall of the reaction tube 203 constituting the processing chamber 201, and the wafer 200. A plurality of gas supply holes 420a for supplying the source gas, are formed on a side face of the nozzle 420. The gas supply holes 420a also have opening areas which are the same from the lower part to the upper part or sloped in sizes toward the upper part, and further they are provided at the same opening pitches.

Further, a carrier gas supply tube 520 for supplying carrier gas, is connected to the second source gas supply tube 320. A second carrier gas supply source not shown, a mass flow controller 522, and a valve 524 are provided to the carrier gas supply tube 520 sequentially from the upstream side.

A catalyst supply source not shown, the mass flow controller 332, and the valve 334 are provided to the catalyst supply tube 330 sequentially from the upstream side. A nozzle 430 is connected to the tip end portion of the catalyst supply tube 330. The nozzle 430 is also extended in the upper and lower direction along the inner wall of the reaction tube 203 in the arc-shaped space between the inner wall of the reaction tube 203 constituting the processing chamber 201, and the wafer 200. A plurality of gas supply holes 430a for supplying the catalyst, are formed on a side face of the nozzle 430. Similarly to the gas supply holes 410a, the catalyst supply holes 430a also have opening areas which are the same from the lower part to the upper part or sloped in sizes toward the upper part, and further they are provided at the same opening pitches.

Further, a carrier gas supply tube 530 for supplying the carrier gas, is connected to the catalyst supply tube 330. A third carrier gas supply source not shown, a mass flow controller 532, and a valve 534 are provided to the carrier gas supply tube 530 sequentially from the upstream side.

An example of the above-described structure is shown as follows. As examples of the source gas, Si contained source (TDMAS: trisdimethylaminosilane (SiH(N(CH₃)₂)₃), DCS: dichlorosilane (SiH₂Cl₂), HCD: hexachloro disilane (Si₂Cl₆), TCS: trichlorosilane (SiCl₄), etc) are introduced to the first source gas supply tube 310. H₂O and H₂O₂, etc, are introduced to the second source gas supply tube 320 as examples of the oxide source. Pyridine (C₅H₅N) and pyrimidine (C₄H₄N₂), quinolin (C₉H₇N), and picoline (C₆H₇N), etc, are introduced to the catalyst supply tube 330.

A first source gas supply system is mainly constituted by the first source gas supply tube 310, first source gas supply source not shown, mass flow controller 312, and valve 314, nozzle 410, gas supply holes 410a, carrier gas supply tube 510, first carrier gas supply source not shown, mass flow controller 512, and valve 514. Further, a second source gas supply system is mainly constituted by the second source gas supply tube 320, a second source gas supply source not shown, mass flow controller 322 and valve 324, nozzle 420, gas supply hole 420a, carrier gas supply tube 520, second carrier gas supply source not shown, mass flow controller 522 and valve 524. Further, a catalyst supply system is constituted mainly by the catalyst supply tube 330, catalyst supply source not shown, mass flow controller 332 and valve 334, nozzle 430, catalyst supply hole 430a, carrier gas supply tube 530, third carrier gas supply source not shown, mass flow controller 532 and valve 534. Then, a gas supply system is constituted mainly by the first source gas supply system, second source gas supply system, and catalysts supply system.

### (Exhaust System)

An exhaust tube 231 for exhausting atmosphere in the processing chamber 201 is connected to a side wall of the manifold 209. APC(Auto Pressure Controller) valve 243e, being a pressure adjuster, and a vacuum pump 246, being a vacuum exhaust device, are provided to the exhaust tube 231 sequentially from the upstream side. Inside of the processing chamber 201 can be set to a desired pressure by adjusting an opening degree of an open/close valve of the APC valve 243e while operating the vacuum pump 246. An exhaust system according to this embodiment for exhausting the inside of the processing chamber 201 is constituted mainly by a gas exhaust hole 212, the exhaust tube 231, a pressure sensor not shown, the APC valve 243e, and the vacuum pump 246.

### (Controller)

A controller 280, being a control part (control means), is connected to each member such as mass flow controllers 312, 322, 332, 512, 522, 532, valves 314, 334, 514, 524, 534, APC valves 243e, heater 207, vacuum pump 246, rotation mechanism 267, and boat elevator 115. The controller 280 is an example of the control part for controlling an overall operation of the substrate processing apparatus 101, and controls flow rates of the mass flow controllers 312, 322, 332, 512, 522, 532, open/close operations of the valves 314, 324, 334, 514, 524, 534, open/close and pressure adjustment operation of the APC valve 243e, temperature adjustment of the heater 207, start/stop of the vacuum pump 246, rotation speed adjustment of the rotation mechanism 267, and elevating operation of the boat elevator 115, respectively.

### (4) Substrate Processing Step

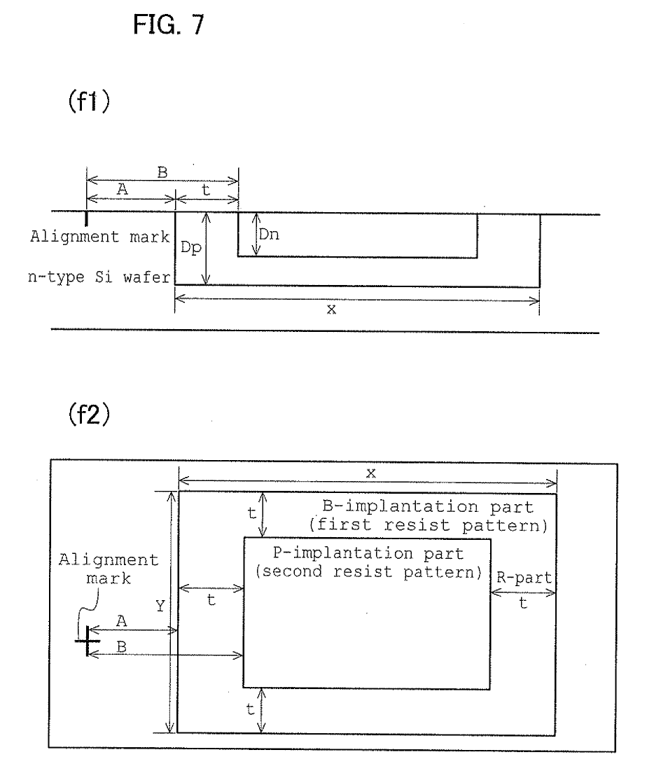

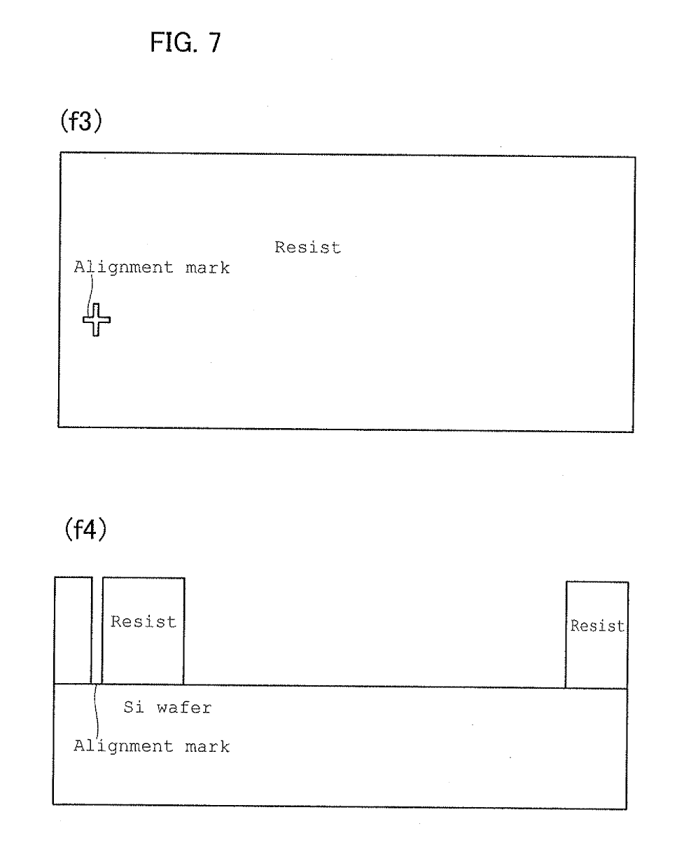

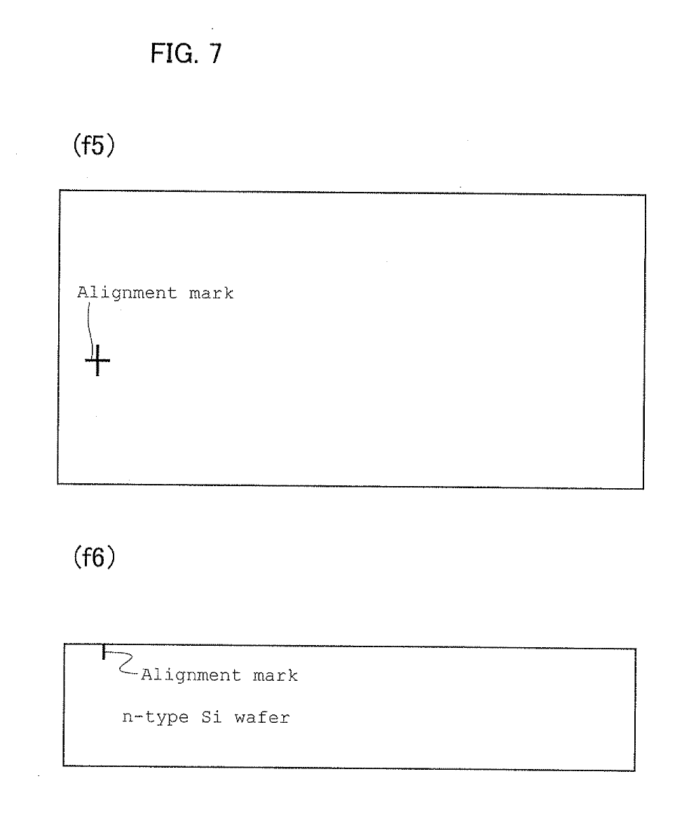

First, prior to the explanation for the substrate processing step according to this embodiment, a conventional substrate processing step will be described for reference. FIG. 7 to FIG. 10 are schematic views showing a step of the substrate processing steps including a conventional ion injection step.

FIG. 7(f1) shows a cross sectional view of a semiconductor device, and FIG. 7(f2) shows a planar view, respectively. In order to manufacture such a semiconductor device, first, a first resist pattern having an opening part with vertical length X and lateral length Y is formed on a n-type Si wafer, then B-ion implantation is carried out in depth Dp, with the first resist pattern as a mask, to thereby prepare p-type semiconductor. Then, a second resist pattern having an opening part with lateral length X−2t and vertical length Y−2t is formed, in such a manner as being uniformly shrunk from the first resist pattern by vertical and lateral lengths t respectively, and P-ion implantation is carried out in depth Dn with the second resist pattern as a mask, to thereby prepare n-type semiconductor.

In this semiconductor device, the p-type semiconductor of the first resist pattern is inserted between the n-type semiconductor and the n-type Si wafer in the second resist pattern. Therefore, electric charge in the second resist pattern does not flow toward the n-type Si wafer or the electric charge is not flown from the Si wafer, by p-n junction between the first resist pattern and the second resist pattern, and p-n junction between the first resist pattern and the n- type Si wafer. Thus, fluctuation of a voltage is suppressed, which occurs due to flowing of the electric charge.

The first resist pattern is formed at a position located away from the alignment mark by A in a lateral direction, and the second resist pattern is formed at a position away from the alignment mark by B in a lateral direction, namely at a position away from the alignment mark by A+t. When this pattern is prepared, both the first resist pattern and the second resist pattern do not involve etching, and therefore can not be used as the alignment mark. Therefore, at least three masks are needed for forming the alignment mark, the first resist pattern, and the second resist pattern, respectively.

A conventional preparation process of this device pattern will be shown in the following (a) to (i),
(a) First, by using a photolithography technique, patterning of a pattern of the alignment mark is applied to the resist formed on the Si wafer. A planar view at this time is shown in FIG. 7(f3), and a cross sectional view thereof is shown in FIG. 7(f4).
(b) Then, etching of the Si wafer surface is carried out, with the resist on which the alignment mark is patterned, as a mask, and the patterning of the alignment mark is applied on the Si wafer.
(c) Then, the resist is removed. Thus, the alignment mark is completed. The planar view at this time is shown in FIG. 7(f5), and a cross sectional view thereof is shown in FIG. 7(f6).
(d) Then, patterning of the first resist pattern is applied to the resist formed on the Si wafer, with the alignment mark as a target (reference position), by using the photolithography technique. At this time, misalignment from the alignment mark is generated (the relative position between the first resist pattern and the alignment mark is deviated from a target position) in some cases. The misalignment is generated in both directions of the vertical direction and the lateral direction. However, only the lateral direction will be described with reference to the figure, for simplifying the explanation.

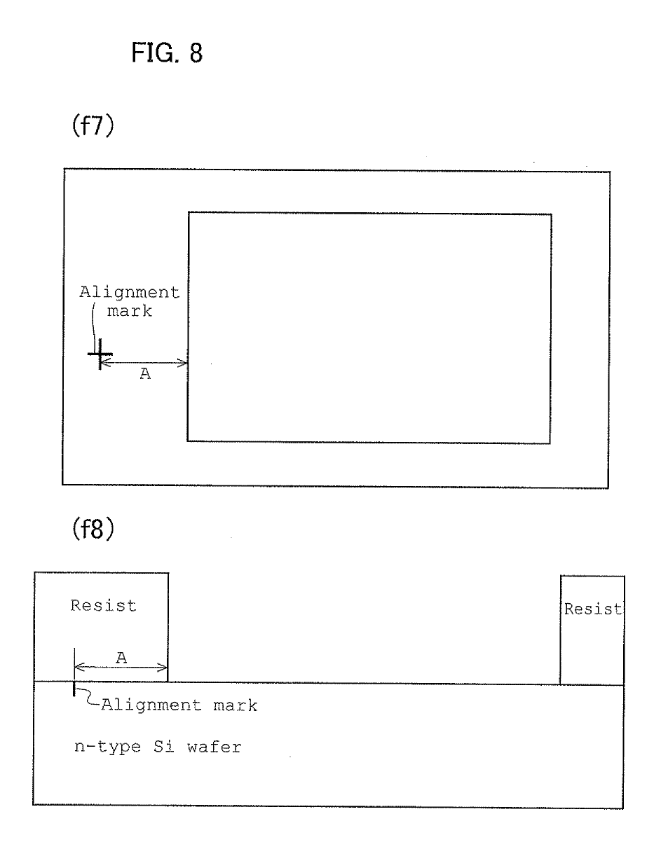

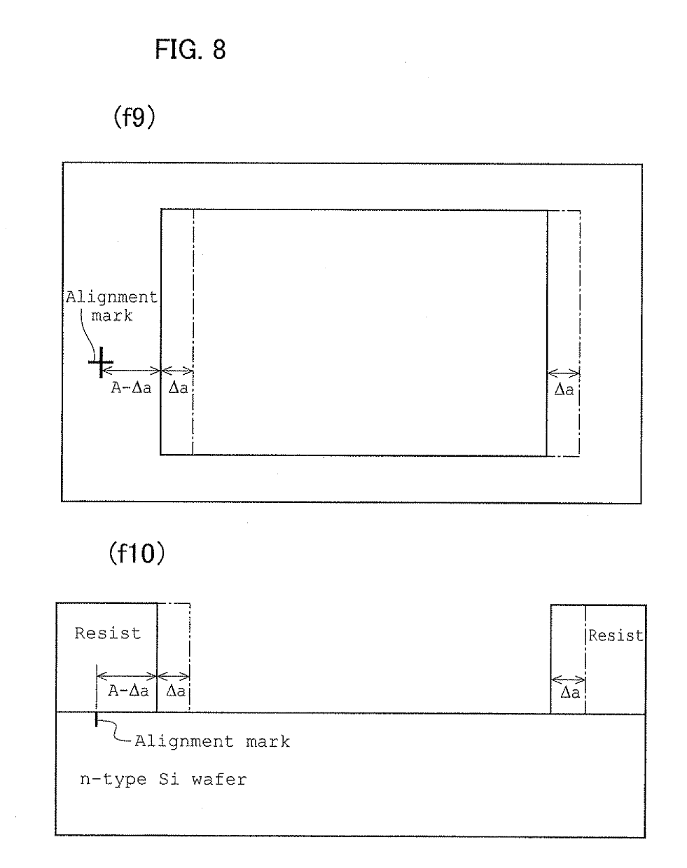

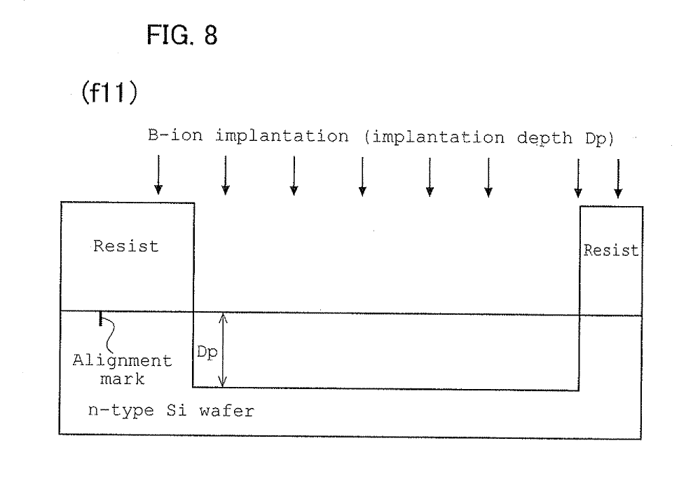

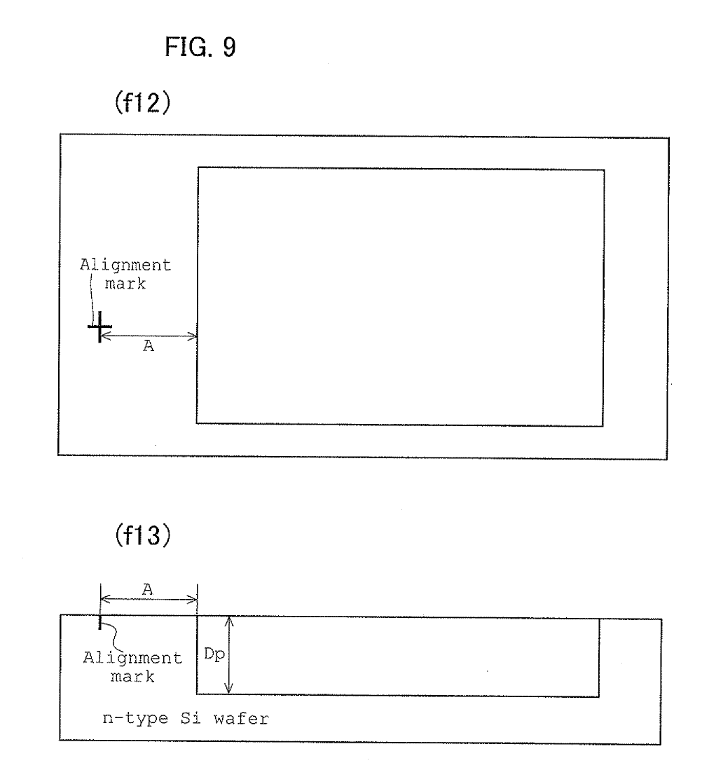

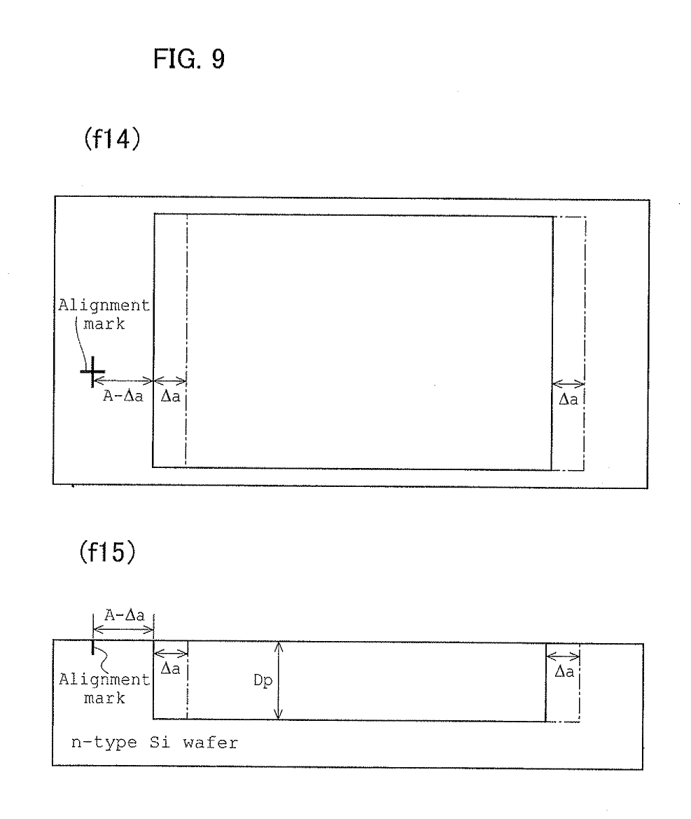

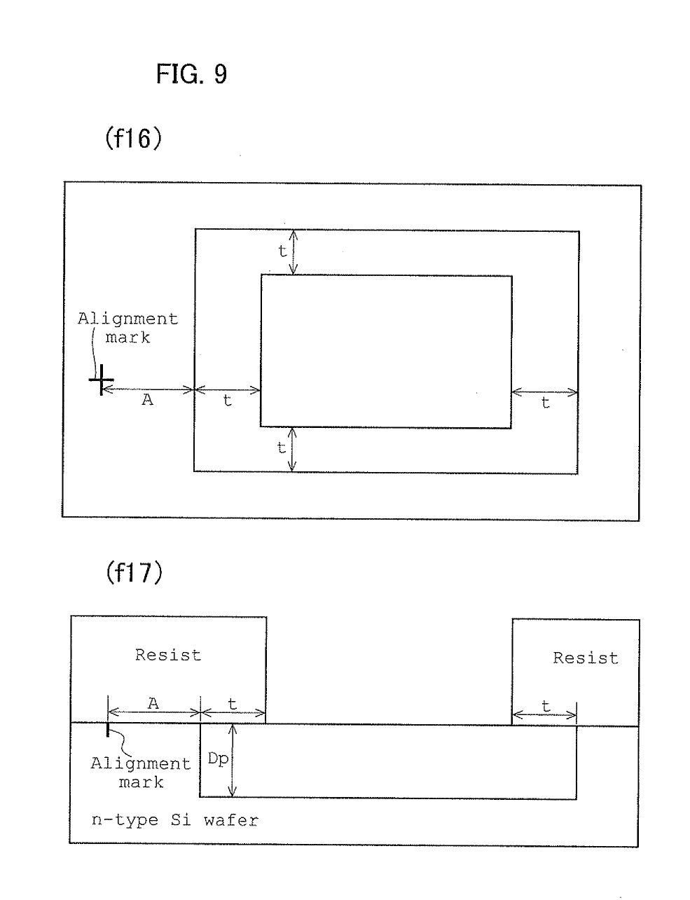

A planar view of the patterning true to a design without misalignment is shown in FIG. 8(f7), and a cross-sectional view thereof is shown in FIG. 8(f8). As shown in FIG. 8(f7) and FIG. 8(f9), A is a distance from the alignment mark prepared in (c) to the first resist pattern. Meanwhile, a planar view showing the misalignment generated by Aa at the left side in the lateral direction is shown in FIG. 8(f9), and a cross sectional view thereof is shown in FIG. 8(f10). In FIG. 8(f9) and FIG. 8(f10), the first resist pattern can be obtained so as to be true to a design, and this case is shown by one dot chain line. As shown in FIG. 8(f9) and FIG. 8(f10), A−Δa is a distance from the alignment mark to the first resist pattern.
(e) Then, boron (B) ion is implanted into the Si wafer surface by depth Dp by using an ion implantation device, with a resist patterned with the first resist pattern as a mask. The cross sectional view of the pattern true to a design is shown in FIG. 8(f11).
(f) Then, the resist patterned with the first resist pattern is removed. A planar view of the pattern true to a design at this time is shown in FIG. 9(f12) and a cross sectional view thereof is shown in FIG. 9(f13). A planar view of the patterning progressed to this step in a state of the misalignment is shown in FIG. 9(f14) and a cross sectional view thereof is shown in FIG. 9(f15). In FIG. 9(f15) and thereafter, a virtual line is shown by one dot chain line in a case that a boron (B) implantation layer of the first resist pattern is formed as designed.
(g) By using the photolithography technique, patterning of the second resist pattern is applied to the resist formed on the Si wafer, with the alignment mark as a target (reference position). At this time as well, the misalignment from the alignment mark is generated (the relative position between the second resist pattern and the alignment mark is deviated from a target position). However, this time as well, only the lateral direction will be described with reference to the figure, for simplifying the explanation.

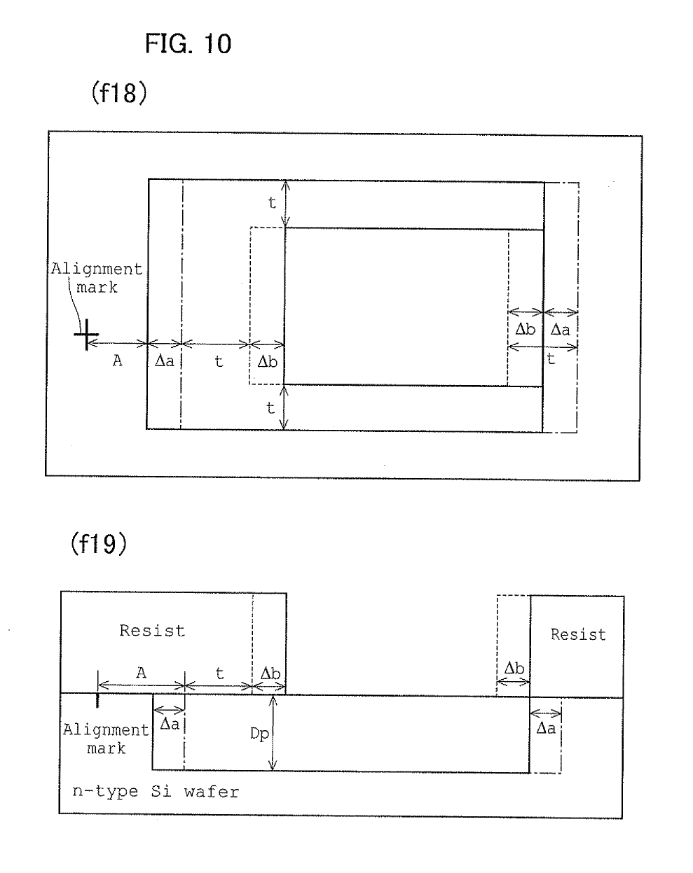

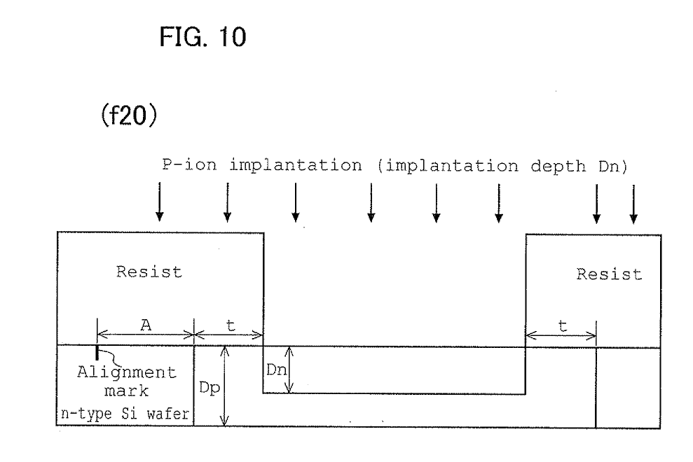

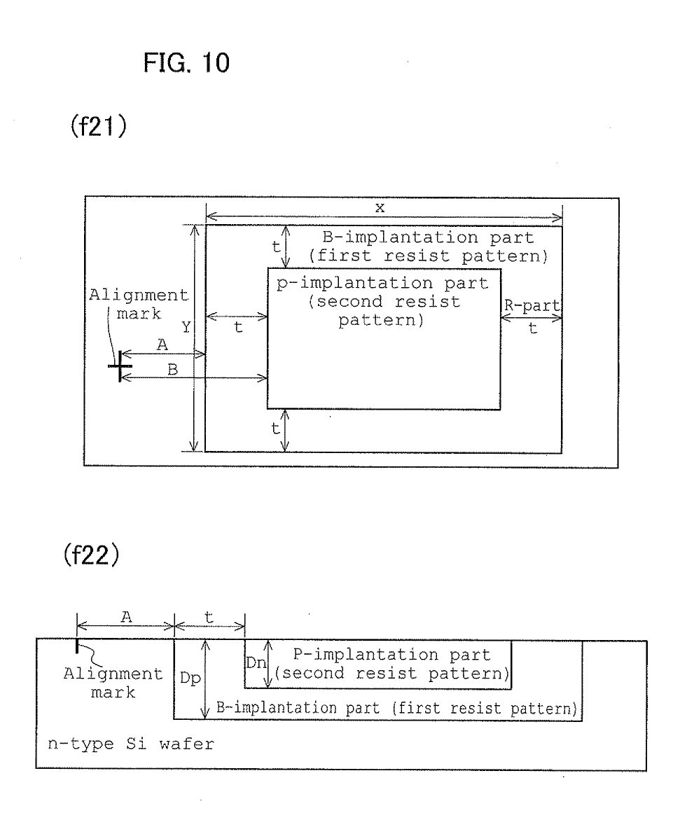

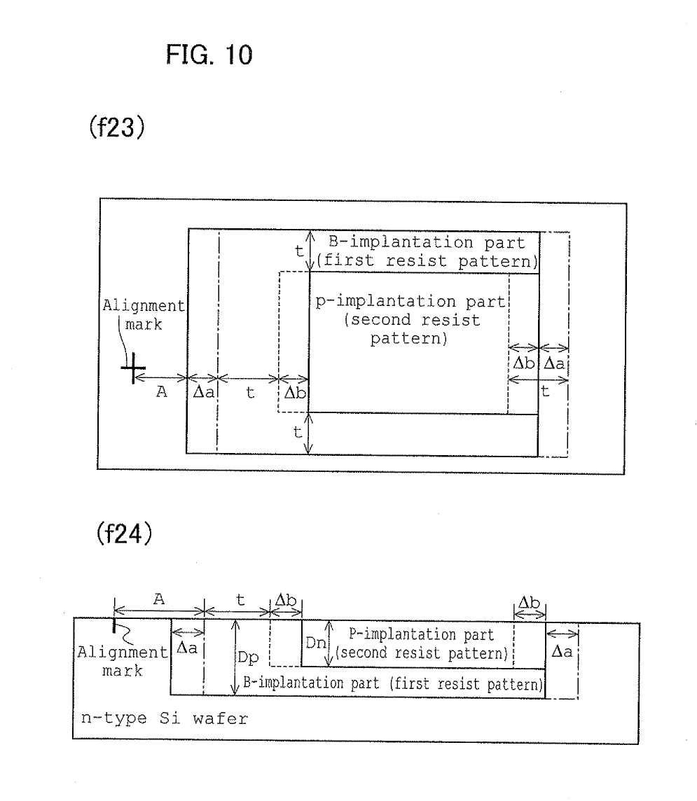

A planar view of the patterning true to a design without misalignment is shown in FIG. 9(f16), and a cross-sectional view thereof is shown in FIG. 9(f17). Neither level difference nor discoloration occurs to a part prepared by the ion implantation of the first resist pattern, and therefore this part is not recognized even if viewed by a metal microscope or viewed by SEM. Therefore, in FIG. 9(f16), this part is shown by thin line. Meanwhile, from FIG. 9(f14) and FIG. 9(f15), it is found that the misalignment occurs by Δb at the right side in the lateral direction, and a planar view of the misalignment satisfying Δa+Δb=t is shown in FIG. 10(f18) and a cross sectional view thereof is shown in FIG. 10(f19). A case of the second resist pattern true to a design is shown by dot line. As shown in FIGS. 10(f18) and (f19), a region where the first resist pattern does not exist is generated between the second resist pattern and the Si wafer.
(h) Then, phosphor (P) ion is implanted into the Si wafer surface by depth Dn by using the ion implantation device, with a resist patterned with the second resist pattern as a mask. The cross sectional view of the pattern true to a design is shown in FIG. 10(f20).
(i) The resist patterned with the second resist pattern is removed, and a conventional substrate processing step is ended. A planar view of the pattern true to a design at this time is shown in FIG. 10(f21) and a cross sectional view thereof is shown in FIG. 10(f22). Meanwhile, the misalignment Δa is generated at the left side during resist patterning of the first resist pattern, and the misalignment Δb is generated at the right side during resist patterning of the second resist pattern, and a planar view of a completion of patterning satisfying Δa+Δb=t is shown in FIG. 10(f23), and a cross sectional view thereof is shown in FIG. 10(f24). In this state, n-type portion of the second resist pattern and n-type Si wafer are brought into contact with each other and shorted, to thereby allow electric charge and electric potential of the second resist pattern to flow to the wafer, and the electric charge and the electric potential can not be retained. Namely, it is found that a device manufactured by using such a wafer can not be used as a device element. Then, from FIG. 10(f23) and FIG. 10(f24), it is found that when satisfying Δa+Δb≧t, n-type portion of the second resist pattern and n-type Si wafer are brought into contact with each other, to thereby allow the electric charge and electric potential of the second resist pattern to flow to the substrate, and the electric charge and the electric potential can not be retained. Further, even if satisfying Δa+Δb<t, distance between the n-type portion of the second resist pattern and the n-type Si wafer, namely, widths of a part where a p-type region of the first resist pattern appears on the surface, are vertically and horizontally changed. In a narrow width portion, there is a problem that an electric field is easily concentrated, thus generating a leak current due to concentration of the electric field, thus allowing the electric charge of the second resist pattern to flow to the Si wafer, and generating the fluctuation in voltage.

In order to prevent such a problem, the misalignment of the first resist pattern from the alignment mark, and the misalignment of the second resist pattern from the alignment mark, need to be strictly controlled. Therefore, the number of regenerations is inevitably increased in the step of patterning the first resist pattern on the resist shown by (d), and the step of patterning the second resist pattern on the resist shown by (g). In order to reduce the number of regenerations, an upper level model with excellent alignment accuracy must be used even in a case that both the first resist pattern and second resist pattern have large dimensions and patterning can be sufficiently possible by an i-ray exposure apparatus, thus involving a higher cost. Further, in the photolithography step of the second resist pattern, there is no first resist pattern, and therefore an amount of shrink of the first resist pattern and B must be obtained indirectly from a value of the misalignment.

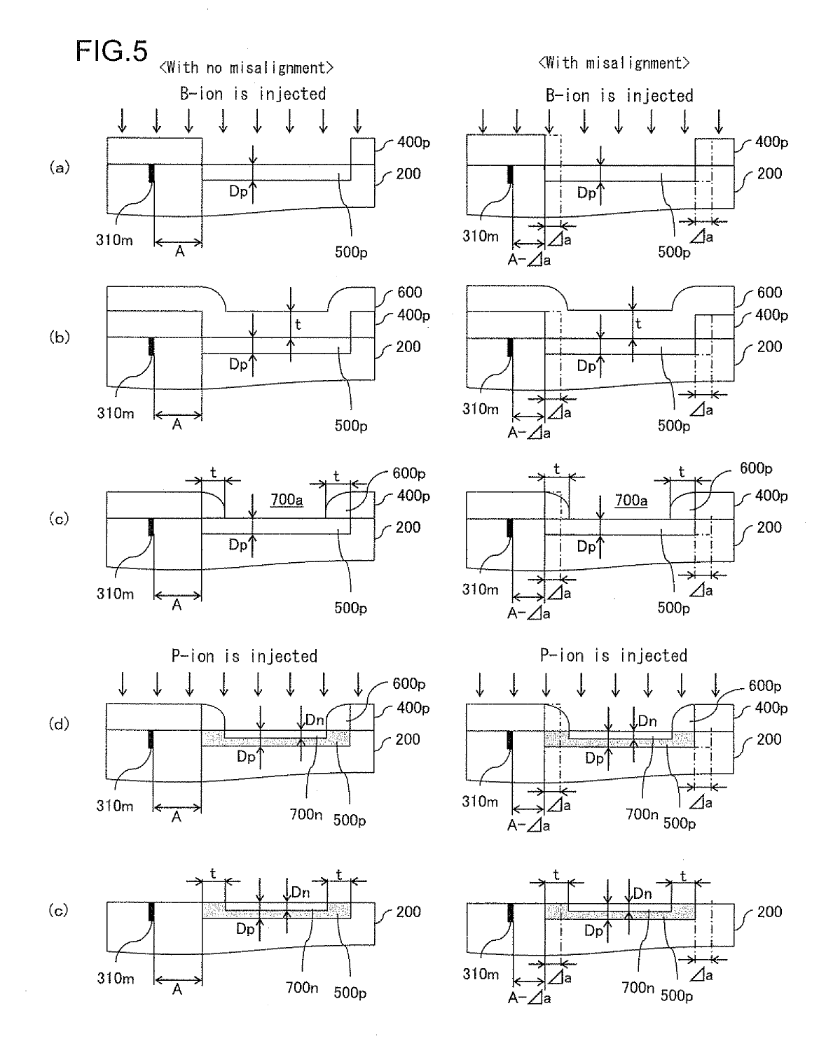

Next, as a step of the manufacturing steps of the semiconductor device according to this embodiment, the substrate processing step of injecting boron (B) ion into a part of the region of the wafer 200, being an n-type silicon substrate; and forming a p-type semiconductor region, being a first ion implantation region, and thereafter injecting phosphor (P) ion into a part of the region in the formed p-type semiconductor region, and forming an n-type semiconductor region, being a second ion implantation region, will be described with reference to FIG. 4 and FIG. 5.

FIG.4 is a schematic view for explaining a first half part of the substrate processing step according to an embodiment of the present invention, showing a state that alignment mark 310m is formed on the wafer 200, and thereafter second resist pattern 400p is formed. FIG. 5 is a schematic view explaining a second half part of the substrate processing step according to an embodiment of the present invention, wherein first ion implantation region 500p is formed with the second resist pattern 400p as an ion injection mask, and thereafter a thin film pattern 600p covering an outer edge of the first ion implantation region 500p is formed, and second ion implantation region 700n is formed with the thin film pattern 600p as an ion injection mask.

### (Step 10)

First, first resist film 300 is formed on the wafer 200. Specifically, the surface of the wafer 200 is baked by being coated with a positive photoresist material or a negative photoresist material, to thereby form the first resist film 300. The first resist film 300 can be made of the positive photoresist material or the negative photoresist material. In the explanation given hereafter, the first resist film 300 is made of the positive photoresist material. The first resist film 300 can be formed, for example, by spin-coating or by using equipment such as a slit coater. A planar view and a cross sectional view of the wafer 200 with the first resist film 300 formed thereon, are shown in FIG. 4(a) respectively.

### (Step 20)

Next, apart of the first resist film 300 is exposed to lights and the resist film after exposure is developed, to thereby form a first resist pattern 300p on the wafer 200. Specifically, the first resist film 300 that covers an alignment mark forming region 310a as will be described later, is irradiated with lights (exposed) from ArF excimer light source (193 nm) and KrF excimer light source (248 nm), etc, via a first photomask (not shown). Thereafter, a part of the first resist film 300 that covers the alignment mark forming region 310a is removed by developing the first resist film 300, to thereby form a first resist pattern 300p on the wafer 200. A planar view and a cross sectional view of the wafer 200 with the first resist pattern 300p formed thereon, are respectively shown in FIG.4(b).

### (Step 30)

Next, alignment mark 310m is formed on the wafer 200, by etching an exposure surface of the wafer 200 (namely, alignment mark forming region 310a), with the first resist pattern 300p as an etching mask. Thereafter, the first resist pattern 300p is removed by using an etching solution. A planar view and a cross sectional view of the wafer 200 after removing the first resist pattern 300p are respectively shown in FIG. 4(c).

### (Step 40)

Next, second resist film 400 is formed on the wafer 200 with the alignment mark 310m formed thereon. Specifically, the surface of the wafer 200 after removing the first resist pattern 300p is baked by being coated with the positive photoresist material or the negative photoresist material, to thereby form a second resist film 400. The second resist film 400 can be made of the positive photoresist material or the negative photoresist material. In the explanation given hereafter, the second resist film 400 is made of the positive photoresist material. The second resist film 400 can be formed, for example, by spin-coating or by using equipment such as a slit coater. A planar view and a cross sectional view of the wafer 200 with the second resist film 400 formed thereon, are shown in FIG. 4(d) respectively.

### (Step 50)

Next, apart of the second resist film 400 is exposed to lights and the resist film after exposure is developed, with the alignment mark 310m as a reference position, to thereby form a second resist pattern 400p on the wafer 200. Specifically, a part of the region (a part of the region of the second resist film 400 that covers first ion implantation region 500a) of the second resist film 400 away from the alignment mark 310m by a prescribed distance (distance A in this embodiment) is irradiated (exposed) with lights from light sources such as ArF excimer light source (193 nm) and KrF excimer light source (248 nm), via a second photomask (not shown). Thereafter, a part of the second resist film 400 that covers the first ion implantation region 500a is removed by developing the second resist film 400, to thereby form the second resist pattern 400p on the wafer 200. FIG.4(e) shows a planar view and a cross sectional view of the wafer 200 on which the second resist pattern 400p is formed with no misalignment.

Note that when the second resist film 400 that covers the first ion implantation region 500a, is irradiated with lights, the relative position between an irradiation position of lights and the alignment mark 310m is not set in a prescribed relation, and the second resist pattern 400p is formed deviated from a specified position in some cases. FIG. 4(f) is a planar view and a cross sectional view of the wafer 200 wherein the second resist pattern 400p approaches the alignment mark 310m by distance Δa, thus generating the misalignment in the second resist pattern 400p.

### (Step 60)

Next, B-ion, being a first ion, is injected into the exposure surface (namely, the first ion implantation region 500a) of the wafer 200 by depth Dp, with the second resist pattern 400p as an ion injection mask, to thereby form a first ion implantation region 500p on the wafer 200. The first ion implantation region 500p is formed as p-type semiconductor by doping a prescribed amount of B-ion into the surface of the wafer 200 which is formed as n-type semiconductor. The left side of FIG. 5(a) is a cross sectional view showing a state that the B-ion is injected into the wafer 200 on which the second resist pattern 400p is formed with no misalignment, and the right side of FIG. 5(a) is a cross sectional view (right) of a state that the B-ion is injected into the wafer 200 on which the second resist pattern is formed with misalignment.

### (Step 70)

Next, a thin film 600 composed of SiO₂ is formed on the second resist pattern 400p and the first ion implantation region 500p so as to have a uniform thickness t, by using the aforementioned substrate processing apparatus. The step of forming the thin film 600 will be described later. The left side of FIG. 5(b) is a cross sectional view showing a state that the thin film 600 is formed on the wafer 200 on which the second resist pattern 400p is formed with no misalignment, and the right side of FIG. 5(b) is a cross sectional view showing a state that the thin film 600 is formed on the wafer 200 on which the second resist pattern 400p is formed with misalignment. Note that in FIG. 5, the second resist pattern 400p has the same thickness as the thickness of the thin film 600 composed of SiO₂. However, the present invention is not limited thereto. For example, the thickness t of the thin film 600 may be either larger or smaller than the thickness of the second resist pattern 400p.

### (Step 80)

Next, by reducing a prescribed thickness of the formed thin film 600 by using anisotropic etching (aching), a part of the first ion implantation region 500p (namely, second ion implantation region 700a) is exposed while leaving the thin film 600 on the side wall of the second resist pattern 400p, and the thin film pattern 600p is formed, so as to cover the outer edge of the first ion implantation region 500p with a constant width. Note that the anisotropic etching can be performed on the thin film 600 by turning CF₄ gas to plasma under an atmospheric pressure and supplying plasma thus obtained to the thin film 600.

The left side of FIG. 5(c) is a cross sectional view showing a state that the thin film pattern 600p is formed on the wafer 200 on which the second resist pattern 400p is formed with no misalignment, and the right side of FIG. 5(c) is a cross sectional view showing a state that the thin film pattern 600p is formed on the wafer 200 on which the second resist pattern 400p is formed with misalignment. The thin film 600 formed so as to have a uniform thickness t is reduced by a prescribed thickness by anisotropic etching (by aching), to form the thin film pattern 600p. Whereby, the thin film pattern 600p is formed so as to cover the outer edge of the first ion implantation region 500p with a constant width (width t in this embodiment), irrespective of presence/absence of the misalignment of the second resist pattern 400p.

### (Step 90)

Next, P-ion, being a second ion, is injected into the exposure surface (namely second ion injecting region 700a) of the first ion implantation region 500p by depth Dn(<Dp), with the thin film pattern 600p as a mask, to thereby form second ion implantation region 700n within the first ion implantation region 500p. The second ion implantation region 700n is formed as n-type semiconductor by being formed by doping a prescribed amount of P-ion into the surface of the first ion implantation region 500p which is formed as p-type semiconductor.

The left side of FIG. 5(d) is a cross sectional view showing a state that the second ion implantation region 700n is formed on the wafer 200 on which the second resist pattern 400p is formed with no misalignment, and the right side of FIG. 5(c) is a cross sectional view showing a state that the second ion implantation region 700n is formed on the wafer 200 on which the second resist pattern 400p is formed with misalignment. As described above, the thin film pattern 600p is formed so as to cover the outer edge of the first ion implantation region 500p with constant width t, irrespective of the presence/absence of the misalignment of the second resist pattern 400p. As a result, the outer edge of the second ion implantation region 700n is surrounded by constant width t by the first ion implantation region 500p, irrespective of the presence/absence of the misalignment of the second resist pattern 400p.

### (Step 100)

Next, the thin film pattern 600p and the second resist pattern 400p are removed. In order to remove the thin film pattern 600p, there are two systems such as a wet etching system and a dry etching system. In order to remove the thin film pattern 600p by the wet etching, for example, a dilute HF aqueous solution, etc, being a hydrofluoric acid (HF) solution, can be used as etching solution. Further, in order to remove the thin film pattern 600p by the dry etching system, for example, oxygen plasma, etc, can be used as etching gas.

### (5) Thin Film Forming Step

Next, the aforementioned thin film forming step (step 70) will be described in detail, with reference to FIGS. 1, 2, 6.

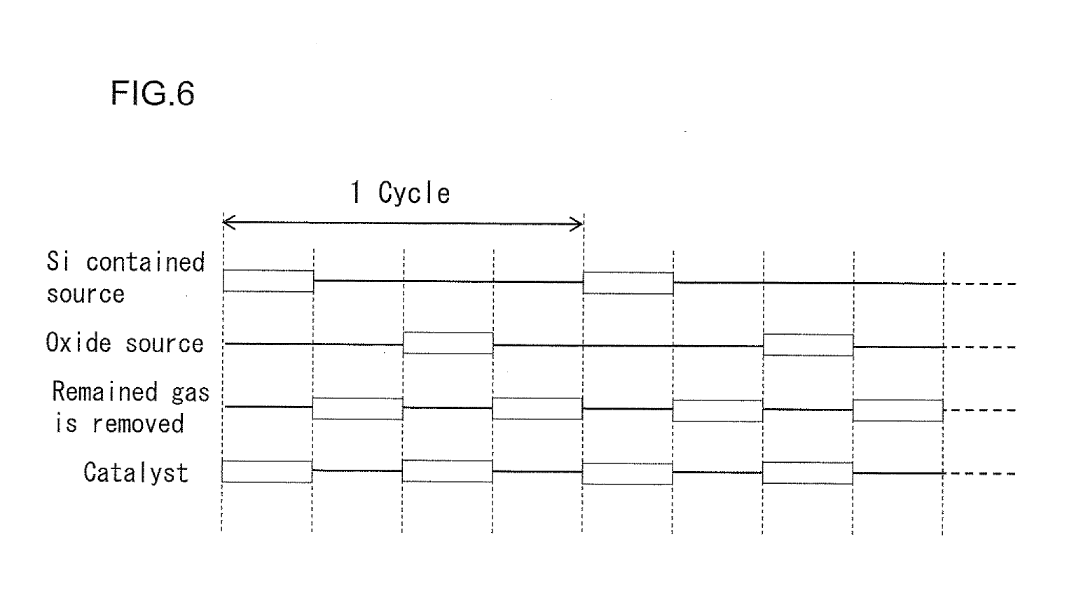

FIG. 6 is a view exemplifying a schematic gas supply sequence when a thin film is formed by ALD (Atomic Layer Deposition) method in the substrate processing step according to this embodiment. The ALD method is one of the CVD (Chemical Vapor Deposition) method, and is a method of forming a film by supplying onto the substrate alternately in each kind of the source gases, being at least two kinds of raw materials used in film formation under a certain film forming condition (temperature and time, etc.), then making the source gas adsorbed on the substrate per less than one atomic layer unit to several atomic layers units, and utilizing the surface reaction. At this time, the film thickness is controlled by the number of cycles for supplying the source gas (for example, the source gas is supplied in 20 cycles when a film of 20 Å is formed under film forming rate of 1 Å/cycle).

Note that the film forming step (step 70) according to this embodiment is executed by the aforementioned substrate processing apparatus. In the explanation given hereafter, the operation of each part constituting the substrate processing apparatus is controlled by controller 280. In this embodiment, HCD is used as the Si contained source, H₂O is used as the oxide source, pyridine is used as the catalyst, and N₂ is used as the carrier gas, respectively.

### (Substrate Loading Step (S71))

First, the aforementioned step 60 is executed, and a plurality of wafers 200 on which the second resist pattern 400p and the first ion implantation region 500p are formed, are charged into the boat 217 (wafer charge). Then, the boat 217 holding the plurality of wafers 200 is elevated by the boat elevator 215 and is loaded into the processing chamber 201 (boat loading). In this state, the lower end of the manifold 209 is sealed by the seal cap 219, via the O-ring 220, being a sealing member.

### (Pressure Reducing and Temperature Rising Step (572))

Subsequently, the inside of the processing chamber 201 is exhausted by the vacuum pump 246 so that the inside of the processing chamber 201 is set to a desired pressure. At this time, the pressure inside of the processing chamber 201 is measured by a pressure sensor not shown, and based on the measured pressure, the opening degree of the APC valve 243e is feedback-controlled. Further, the inside of the processing chamber 201 is heated by the heater 207 so as to be, for example, 150° C. or less preferably 100° C. or less, and more preferably 75° C., being a lower temperature (extremely lower temperature) than an alteration temperature of the second resist pattern 400p (520). At this time, energization condition to the heater 207 is feedback-controlled based on temperature information detected by the temperature sensor, so that the inside of the processing chamber 201 is set to be a desired temperature distribution. Then, the boat 217 is rotated by the rotation mechanism 267, to thereby rotate the wafer 200.

### (Film Forming Step (S73))

Subsequently, the thin film 600 made of SiO₂ is formed on the second resist pattern 400p and the first ion implantation region 500p at the extremely low temperature, by setting four steps (step 3a to step 73d) as will be described later as one cycle and repeating this cycle multiple number of times.

(Si Contained Source Supplying Step (step 73a))

Valves 314, 334, 514, 524, and 534 are suitably opened in a state that H₂O is introduced into the second source gas supply tube 320, the catalyst is introduced into the catalyst supply tube 330, and N₂ is introduced into carrier gas supply tubes 510, 520, and 530. However, the valve 324 remains to be closed.

As a result, as shown in FIG. 6, HCD is circulated through the first source gas supply tube 310 while mixing with N₂, then is flown into the nozzle 410, and is supplied into the processing chamber 201 from the gas supply holes 410a. Further, the catalyst is also circulated through the catalyst supply tube 330 while mixing with N₂, then is flown into the nozzle 430, and is supplied into the processing chamber 201 from the catalyst supply holes 430a. Further, N₂ is circulated through the carrier gas supply tube 520, then is flown into the nozzle 420, and is supplied into the processing chamber 201 from the gas supply holes 420a. The HCD and the catalyst supplied into the processing chamber 201, pass over the surface of the wafer 200 and are exhausted from the exhaust tube 231.

In step 73a, the time for supplying the catalyst is set to be an optimal time (for example, 10 seconds) by controlling the valves 314 and 334. Further, the valves 314 and 334 are controlled so that the ratio of supply amounts of the HCD and catalyst can be a constant ratio (for example 1:1). Simultaneously, the pressure in the processing chamber 201 is set to be an optimal value (for example, 3 Torr) within a constant range by properly adjusting the APC valve 243e. In the aforementioned step 73a, gas molecule of HCD of less than one atomic layer to several atomic layers is adsorbed on the second resist pattern 400p formed on the wafer 200 and on the first ion implantation region 500p.

(Purging Step (Step 73b))

Supply of the catalyst is stopped by closing the valves 314 and 334 and as shown in FIG. 6, N₂ is continued to be supplied into the processing chamber 201 from the carrier gas supply tubes 510, 520, and 530, so that the inside of the processing chamber 201 is purged by N₂. Purging time is for example set to be 15 seconds. Further, there may be two steps of purging and vacuuming within 15 seconds. As a result, the HCD and catalyst remained in the processing chamber 201 are excluded (removed) from the processing chamber 201.

(Oxide Source Supplying Step (Step 73c))

Valves 324 and 334 are suitably opened while opening the valves 514, 524, and 534. The valve 314 is remained to be closed. As a result, as shown in FIG. 6, H₂O is circulated through the second source gas supply tube 320 while mixing with N₂, then is flown into the nozzle 420, and is supplied into the processing chamber 201 from the gas supply holes 420a. Further, the catalyst is also circulated through the catalyst supply tube 330 while mixing with N₂, then is flown into the nozzle 430, and is supplied into the processing chamber 201 from the catalyst supply holes 430a. Further, N₂ is circulated through the carrier gas supply tube 510, then is flown into the nozzle 410, and is supplied into the processing chamber 201 from the gas supply holes 410a. The H₂O and catalyst supplied into the processing chamber 201 are passed over the surface of the wafer 200 and are exhausted from the exhaust tube 231.

In step 73c, the time for supplying the catalyst is set to be an optimal time (for example, 20 seconds) by controlling the valves 324 and 334. Further, the valves 314 and 334 are controlled so that the ratio of supply amounts of the H₂O and catalyst can be a constant ratio (for example 1:1). Simultaneously, the pressure in the processing chamber 201 is set to be an optimal value (for example, 7 Torr) within a constant range by properly adjusting the APC valve 243e. In the aforementioned step 73c, SIO₂ film of less than one atomic layer to several atomic layers is formed on the second resist pattern 400p formed on the wafer 200 and on the first ion implantation region 500p. Note that supply concentrations of the H₂O and catalyst are preferably the same concentrations.

Note that according to required characteristics as the oxide source (raw material corresponding to H₂O) supplied in step 73c, the molecule of the oxide source includes an atom having higher electronegativity, and therefore the oxide source is electrically biased. This is because since the catalyst has a high electronegativity of the catalyst, activation energy of the source gas is decreased and a reaction is accelerated. Accordingly, as the source gas supplied in step 73c, H₂O and H₂O₂, etc, having OH-bond are appropriate and non-polar molecules such as O₂ and O₃ are inappropriate.

(Purging Step (Step 73d))

Supply of the catalyst is stopped by closing the valves 324 and 334 and as shown in FIG. 6, N₂ is continued to be supplied into the processing chamber 201 from the carrier gas supply tubes 510, 520, and 530, so that the inside of the processing chamber 201 is purged by N₂. Purging time is for example set to be 15 seconds. Further, there may be two steps of purging and vacuuming within 15 seconds. As a result, the H₂O and catalyst remained in the processing chamber 201 is excluded (removed) from the processing chamber 201.

Thereafter, steps 73a to 73d are set as one cycle, and by repeating this cycle multiple number of times, the thin film 600 made of SiO₂ is formed on the second resist pattern 400p formed on the wafer 200, and on the first ion implantation region 500p. In this case, the film formation is performed, so that atmosphere formed by the Si contained source and the catalyst in step 73a, and atmosphere formed by the oxide source and the catalyst in step 73c, are not mixed with each other in the processing chamber 201.

### (Pressure Increasing Step (S40) and Substrate Unloading Step (S50))

Thereafter, the inside of the processing chamber 201 is vacuumized and the HCD and H₂O, and catalyst remained in the processing chamber 201 are exhausted, and the inside of the processing chamber 201 is set to be an atmospheric pressure by controlling the APC valve 243e, and the boat 217 is unloaded from the processing chamber 201. Thus, a single film formation processing (batch processing) is ended.

### (6) Effects of this Embodiment

According to this embodiment, one or a plurality of effects shown below are exhibited.
(a) According to this embodiment, a first photomask (not shown) for forming the alignment mark 310m is used, and a second photomask (not shown) for forming the second resist pattern 400p is used. However, no photomask is used in step 80 for forming the thin film pattern 600p. Accordingly, the number of photomasks is reduced to two, thus making it possible to reduce the manufacturing cost of the semiconductor device.

Meanwhile, as described above, in a method of previously forming the alignment mark on a substrate; thereafter forming the first resist pattern on the substrate, with the alignment mark as a reference position; and thereafter forming the second resist pattern on the substrate with the alignment mark as a reference position, three photomasks are required in total, such as a photomask for forming the alignment mark, a photomask for forming the first resist pattern, and a photomask for forming the second resist pattern, thus increasing the manufacturing cost of the semiconductor device in some cases.
(b) According to this embodiment, in step 70 for forming the thin film 600, the inside of the processing chamber 201 is set to be 150° C. or less, preferably 100° C. or less, and more preferably 75° C. Thus, alteration and deformation of the second resist pattern 400p caused by forming the thin film 600, can be suppressed. As a result, for example due to a peel-off of the second resist pattern 400p, it is possible to prevent a situation that P-ion, etc, is injected into the base of the second resist pattern 400p in step 90, and the peeled second resist pattern 400p becomes a foreign matter. Therefore, the manufacturing yield of the semiconductor device can be improved. Further, by suppressing the deformation of the second resist pattern 400p, the deformation of the thin film pattern 600p formed in step 80 can be suppressed, and the shape and position of the second ion implantation region 700n can be accurately controlled. Therefore, the manufacturing yield of the semiconductor device can be improved.

Meanwhile, as described above, in a method of previously forming the alignment mark on a substrate; thereafter forming the first resist pattern on the substrate with the alignment mark as a reference position, and thereafter forming the second resist pattern on the substrate with the alignment mark as a reference position, the first resist pattern is damaged by heat and solvent when the second resist pattern is formed, and a desired shape of the ion injection mask can not be obtained, or a quality of the ion injection mask is deteriorated, and the first resist pattern is peeled-off, resulting in a foreign matter in some cases.
(c) According to this embodiment, in step 70, the thin film 600 made of SiO₂ is formed on the second resist pattern 400p and on the first ion implantation region 500p so as to have a uniform thickness t. Then, in step 80, the thin film pattern 600p is formed by reducing the thin film 600 formed to have a uniform thickness t by a prescribed thickness, using anisotropic etching. As a result, the thin film pattern 600p covers the outer edge of the first ion implantation region 500p with a constant width (width t in this embodiment), irrespective of the presence/absence of the misalignment of the second resist pattern 400p. Then, in step 90, the second ion implantation region 700n is formed within the first ion implantation region 500p, by injecting the P-ion into the exposure surface of the first ion implantation region 500p, with the thin film pattern 600p as a mask. As a result, the outer edge of the second ion implantation region 700n is surrounded by the first ion implantation region 500p with constant width t, irrespective of the presence/absence of the misalignment of the second resist pattern 400p. Namely, the shape and position of the second resist pattern 400p are controlled in a self-aligning manner, and therefore the relative positional relation between the first ion implantation region 500p and the second ion implantation region 700n, and the shape of the second ion implantation region 700n are maintained to be constant, irrespective of the presence/absence of the misalignment of the second resist pattern 400p. As a result, the manufacturing yield of the semiconductor device can be improved.

Meanwhile, in a method of previously forming the alignment mark on the substrate; thereafter forming the first resist pattern on the substrate with the alignment mark as a reference position, and thereafter forming the second resist pattern on the substrate with the alignment mark as a reference position, for example when a misalignment is generated in the formation position of the first resist pattern, the relative position between the first resist pattern and the second resist pattern does not fall within an allowable range even if the formation position of the second resist pattern is accurate, and a desired shape of the ion injection mask can not be obtained in some cases. As a result, irregular shape and position of an ion implantation region on the substrate are formed, to thereby deteriorate a production yield of the semiconductor device in some cases. For example, when the outer edge of the first ion implantation region 500p and the outer edge of the second ion implantation region 700n are excessively approached and shorted, the electric field between the first ion implantation region 500p and the second ion implantation region 700n is strengthened, resulting a leak of the electric charge that should be enclosed in the second ion implantation region 700n, via the first ion implantation region 500p, thus making it impossible to retain the electric potential of the second ion implantation region 700n in some cases.
(d) According to this embodiment, the thin film 600 is formed by ALD method in step 70. Thus, the film thickness t of the thin film 600 can be easily accurately controlled by controlling the number of cycles when the steps from step 73a to step 73d are set as one cycle. As a result, the shape and position of the thin film pattern 600p can be further accurately controlled and the shape and position of the second ion implantation region 700n can be further accurately controlled, thus making it possible to improve the manufacturing yield of the semiconductor device.
(e) According to this embodiment, in the Si contained source supplying step (step 73a), the catalyst is supplied into the processing chamber 201 together with the Si contained source, and in the oxide source supplying step (step 73c), the catalyst is supplied into the processing chamber 201 together with the oxide source. As a result, the temperature inside of the processing chamber 201 for forming the thin film 600 can be set to be a lower temperature. Thus, the alteration and deformation of the second resist pattern 400p due to formation of the thin film 600 can be further suppressed.
(f) According to this embodiment, SiO₂ that forms the thin film pattern 600p has a high wet etching rate. Therefore, in step 100, the thin film pattern 600p can be easily removed, thus making it possible to improve the productivity of the semiconductor device and improve the manufacturing yield.

### Other Embodiment of the Present Invention

As described above, the embodiments of the present invention have been specifically described. However, the present invention is not limited thereto, and can be variously modified in a range not departing the gist of the present invention.

For example, the present invention is not limited to a case that the thin film 600 is made of SiO₂, and can be suitably applied to a case that the thin film 600 is made of other films such as SiO, SiCN, SiC, SiOC, SiN, SiEN, SiOC, SiON, and SiOCN. Note that as film forming methods of the thin film 600, either one of the ALD and CVD, or oxidizing, carbonizing, and nitriding methods using heat and plasma may be acceptable. Further, used gas species is not limited to the aforementioned embodiments, and other gas species may also be used. Moreover, the present invention is not limited to a case of using the catalyst, and can be suitably applied to a case that the thin film 600 is formed without using the catalyst.

Further, in the present invention, the width of the thin film pattern 600p that covers the outer edge of the first ion implantation region 500p may be measured by using SEM (Scanning Electron Microscope), etc, in a period after the thin film pattern 600p is formed in step 80, until the thin film pattern 600p is removed in step 100. Neither level difference nor discoloration occurs to the region formed by ion injection, and therefore border between the first ion implantation region 500p and the second ion implantation region 700n are hardly inspected in many cases. Meanwhile, as described above, by measuring the width of the thin film pattern 600p, the width of the first ion implantation region 500p surrounding the outer periphery of the second ion implantation region 700n can be indirectly obtained.

Note that the present invention provides a method of supplying a desired pattern by eliminating the need for masking newly, and therefore can be suitably applied to a case other than the aforementioned embodiments. Also, the present invention can be suitably applied to a method of confirming an amount of shrink of the resist pattern formed by using the photomask.

### Preferred Aspects of the Present Invention

Preferred aspects of the present invention will be additionally described hereafter.

According to an aspect of the present invention, a manufacturing method of a semiconductor device is provided, comprising the steps of:

forming a first resist film on a substrate;

forming a first resist pattern on the substrate by exposing a part of the first resist film to lights and developing the resist film after exposure;

forming an alignment mark on the substrate by etching an exposure surface of the substrate, with the first resist pattern as a mask;

removing the first resist pattern;

forming a second resist film on the substrate on which the alignment mark is formed;

forming a second resist pattern on the substrate by exposing a part of the second resist film to lights, with the alignment mark as a reference position, and developing the resist film after exposure;

forming a first ion implantation region on the substrate by injecting a first ion into the exposure surface of the substrate, with the second resist pattern as a mask;

forming a thin film on the second resist pattern and on the first ion implantation region;

forming a thin film pattern that covers an outer edge of the first ion implantation region by exposing a part of the first ion implantation region by reducing the thin film by a specified thickness while leaving the thin film on a side wall of the second resist pattern;

forming a second ion implantation region within the first ion implantation region by injecting a second ion into the exposure surface of the first ion implantation region with the thin film pattern as a mask; and

removing the thin film pattern and the second resist pattern.

Preferably, in the step of forming the thin film on the second resist pattern and on the first ion implantation region, the Si contained source supplying step for supplying a Si contained source and a catalyst to the second resist pattern and to the first ion implantation region, and the oxide source supplying step for supplying an oxide source and a catalyst to the second resist pattern and to the first ion implantation region, are set as one cycle, and this cycle is repeated multiple number of times.

Further preferably, in the step of forming a thin film on the second resist pattern and on the first ion implantation region, a temperature of the substrate is set to be a lower temperature than an alteration temperature of the first resist pattern.

Further preferably, the Si contained source includes any one of SiH(N(CH₃)₂)₃, SiH₂Cl₂, Si₂Cl₆, SiCl₄, and the oxide source contains either one of H₂O and H₂O₂, and the catalyst includes any one of C₅H₅N, C₄H₄N₂, and C₉H₇N.

Further preferably, the step of measuring a width of the thin film pattern that covers an outer edge of the first ion implantation region, is provided.

Further preferably, the first ion is a boron ion, and the second ion is a phosphor ion.

According to other aspect of the present invention, a substrate processing apparatus is provided, comprising:

a processing chamber that processes substrates;

a first source gas supply system that supplies Si contained source into the processing chamber;

a second source gas supply system that supplies an oxide source into the processing chamber;

a catalyst supply system that supplies a catalyst into the processing chamber;

a heating unit that heats the substrates; and

a controller that controls at least the first source gas supply system, the second source gas supply system, the catalyst supply system, and the heating unit, so as to repeat a cycle of a Si contained source supplying step for supplying the Si contained source and the catalyst into the processing chamber, and an oxide source supplying step for supplying the oxide source and the catalyst into the processing chamber, with this cycle set as one cycle.

What is claimed is:

1. A manufacturing method of a semiconductor device, comprising the steps of:
forming a first resist film on a substrate;
forming a first resist pattern on the substrate by exposing a part of the first resist film to lights and developing the resist film after exposure;
forming an alignment mark on the substrate by etching an exposure surface of the substrate, with the first resist pattern as a mask;
removing the first resist pattern;
forming a second resist film on the substrate on which the alignment mark is formed;
forming a second resist pattern on the substrate by exposing a part of the second resist film to lights, with the alignment mark as a reference position, and developing the resist film after exposure;
forming a first ion implantation region on the substrate by injecting a first ion into the exposure surface of the substrate, with the second resist pattern as a mask;
forming a thin film on the second resist pattern and on the first ion implantation region;
forming a thin film pattern that covers an outer edge of the first ion implantation region by exposing a part of the first ion implantation region by reducing the thin film by a specified thickness while leaving the thin film on a side wall of the second resist pattern;
forming a second ion implantation region within the first ion implantation region by injecting a second ion into the exposure surface of the first ion implantation region with the thin film pattern as a mask; and
removing the thin film pattern and the second resist pattern.

2. A manufacturing method of a semiconductor device according to claim 1, wherein in the step of forming the thin film on the second resist pattern and on the first ion implantation region, the Si contained source supplying step for supplying a Si contained source and a catalyst to the second resist pattern and to the first ion implantation region, and the oxide source supplying step for supplying an oxide source and a catalyst to the second resist pattern and to the first ion implantation region, are set as one cycle, and this cycle is repeated multiple number of times.

3. A manufacturing method of a semiconductor device according to claim 1, wherein in the step of forming a thin film on the second resist pattern and on the first ion implantation region, a temperature of the substrate is set to be a lower temperature than an alteration temperature of the first resist pattern.

4. A manufacturing method of a semiconductor device according to claim 1, wherein the Si contained source includes any one of SiH(N(CH₃)₂)₃, SiH₂Cl₂, Si₂Cl₆, SiCl₄, and the oxide source includes either one of H₂O and H₂O₂, and the catalyst includes any one of C₅H₅N, C₄H₄N₂, and C₉H₇N.

5. A manufacturing method of a semiconductor device according to claim 1, further comprising the step of measuring a width of the thin film pattern that covers an outer edge of the first ion implantation region.

6. A manufacturing method of a semiconductor device according to claim 1, wherein the first ion is a boron ion, and the second ion is a phosphor ion.

7. A substrate processing apparatus, comprising:
a processing chamber that processes substrates;
a first source gas supply system that supplies Si contained source into the processing chamber;
a second source gas supply system that supplies an oxide source into the processing chamber;
a catalyst supply system that supplies a catalyst into the processing chamber;
a heating unit that heats the substrates; and
a controller that controls at least the first source gas supply system, the second source gas supply system, the catalyst supply system, and the heating unit, so as to repeat a cycle of a Si contained source supplying step for supplying the Si contained source and the catalyst into the processing chamber, and an oxide source supplying step for supplying the oxide source and the catalyst into the processing chamber, with this cycle set as one cycle.
